(19) United States
(12) Patent Application Publication
(10) Pub. No.: US 2025/0079413 A1
(43) Pub. Date: Mar. 6, 2025

(54) SEMICONDUCTOR DEVICE

(71) Applicant: FUJI ELECTRIC CO., LTD., Kawasaki-shi (JP)

(72) Inventors: Akira HIRAO, Matsumoto-city (JP); Yoshinari IKEDA, Matsumoto-city (JP); Motohito HORI, Matsumoto-city (JP)

(73) Assignee: FUJI ELECTRIC CO., LTD., Kawasaki-shi (JP)

(21) Appl. No.: 18/802,110

(22) Filed: Aug. 13, 2024

(30) Foreign Application Priority Data
Aug. 30, 2023 (JP) 2023-139871

(51) Int. Cl. H01L 25/11; H01L 23/00; H01L 23/367; H05K 1/11

(52) U.S. Cl. CPC H01L 25/115; H01L 23/367; H01L 24/40; H01L 24/48; H05K 1/115; H01L 24/32; H01L 24/73; H01L 2224/32227; H01L 2224/40155; H01L 2224/48155; H01L 2224/73221; H01L 2224/73263; H01L 2224/73265; H01L 2924/13091; H05K 2201/10166

(57) ABSTRACT

A semiconductor device includes: first and second semiconductor chips provided separately from each other, each semiconductor chip including a first main electrode on a top surface side and a second main electrode on a bottom surface side; and a printed circuit board provided at a circumference of the first and second semiconductor chips, the printed circuit board including a plurality of wiring layers including a first wiring layer which is an uppermost layer electrically connected to the first main electrode of the first semiconductor chip through a connection member, and a second wiring layer which is a lowermost layer electrically connected to the first wiring layer through a via and further to the second main electrode of the second semiconductor chip, and an insulating layer provided between the respective wiring layers.

### CROSS-REFERENCE TO RELATED APPLICATION

This application claims benefit of priority under 35 USC 119 based on Japanese Patent Application No. 2023-139871 filed on Aug. 30, 2023, the entire contents of which are incorporated by reference herein.

### BACKGROUND OF THE INVENTION

### 1. Field of the Invention

The present invention relates to semiconductor devices (semiconductor modules) internally equipped with power semiconductor elements.

### 2. Description of the Related Art

WO2018/181523A1 discloses a composite ceramic multilayer substrate including a glass ceramic insulating layer including a wiring layer, and a highly thermally conductive ceramic insulating layer made of a ceramic material having a higher thermal conductivity than the glass ceramic insulating layer, wherein the glass ceramic insulating layer is provided on one main surface of the highly thermally conductive ceramic insulating layer or both main surfaces of the highly thermally conductive ceramic insulating layer directly and/or with a wiring layer interposed therebetween, and when viewed in a direction perpendicular to a main surface of the composite ceramic multilayer substrate, the composite ceramic multilayer substrate includes at least one heat generating element-mounting portion which is surrounded by the glass ceramic insulating layer and at which a heat generating element-mounting wiring line provided on the main surface of the highly thermally conductive ceramic insulating layer is exposed.

WO2018/179538A1 discloses a semiconductor module including a power wiring line provided with a power element, a glass ceramic multilayer substrate provided with a control element to control the power element, and a highly heat-conductive ceramic substrate made of a ceramic material having higher thermal conductivity than a glass ceramic contained in the glass ceramic multilayer substrate, wherein the power wiring line is disposed on the highly heat-conductive ceramic substrate, and the glass ceramic multilayer substrate is disposed directly on the highly heat-conductive ceramic substrate.

JP04-288854A discloses a structure including a low-temperature sintered multilayer substrate, an aluminum nitride substrate, and a bonding layer interposed between these substrates so as to stably bond the substrates together, wherein the bonding layer includes glass paste. JP02-238642A discloses a ceramic circuit substrate having a structure including a glass ceramic sheet mounted on an aluminum nitride substrate and provided with holes for mounting semiconductor chips in the middle. JP2021-141220A discloses that a control wiring substrate is mounted on a stacked substrate via bonding material, and that the control wiring substrate is implemented by a plurality of substrates.

When such a conventional semiconductor module has a configuration in which power semiconductor elements mounted on an insulated circuit substrate are connected to a terminal case or external connection terminals via connection members such as bonding wires, a bonding area (a connection area) needs to be ensured on the insulated circuit substrate, which impedes a reduction in size of the semiconductor module.

Further, if a printed circuit board is opposed to the upper side of the power semiconductor elements mounted on the insulated circuit substrate so as to be connected to each other via pin terminals, some of the components, such as the power semiconductor elements, would be hidden by the printed circuit board, which impedes an alignment during packaging of the components or an inspection of bonded parts, leading to a decrease in quality.

### SUMMARY OF THE INVENTION

In view of the foregoing problems, the present invention provides a semiconductor device having a configuration that can facilitate a reduction in size and avoid a decrease in quality.

An aspect of the present invention inheres in a semiconductor device including: first and second semiconductor chips provided separately from each other, each semiconductor chip including a first main electrode on a top surface side and a second main electrode on a bottom surface side; and a printed circuit board provided at a circumference of the first and second semiconductor chips, the printed circuit board including a plurality of wiring layers including a first wiring layer which is an uppermost layer electrically connected to the first main electrode of the first semiconductor chip through a connection member, and a second wiring layer which is a lowermost layer electrically connected to the first wiring layer through a via and further to the second main electrode of the second semiconductor chip, and an insulating layer provided between the respective wiring layers.

### BRIEF DESCRIPTION OF THE DRAWINGS

FIG. 1 is a top view illustrating a semiconductor device according to a first embodiment;

FIG. 2 is a cross-sectional view in a vertical direction taken along line A-A′ in FIG. 1;

FIG. 3 is a cross-sectional view in a horizontal direction passing through lowermost wiring layers of a printed circuit board;

FIG. 4 is a cross-sectional view in the horizontal direction passing through second wiring layers from the bottom of the printed circuit board;

FIG. 5 is a cross-sectional view in the horizontal direction passing through third wiring layers from the bottom of the printed circuit board;

FIG. 6 is a cross-sectional view in the horizontal direction passing through uppermost wiring layers of the printed circuit board;

FIG. 7 is an equivalent circuit diagram illustrating the semiconductor device according to the first embodiment;

FIG. 8 is a cross-sectional view in a vertical direction illustrating a semiconductor device of a first comparative example;

FIG. 9 is a side view illustrating a semiconductor device of a second comparative example;

FIG. 10 is a top view illustrating a semiconductor device according to a second embodiment;

FIG. 11 is a cross-sectional view in a vertical direction taken along line A-A′ in FIG. 10;

FIG. 12 is a top view illustrating a semiconductor device according to a third embodiment;

FIG. 13 is a cross-sectional view in a vertical direction taken along line A-A′ in FIG. 12;

FIG. 14 is a top view illustrating a semiconductor device according to a fourth embodiment; and

FIG. 15 is a cross-sectional view in a vertical direction illustrating a semiconductor device according to a fifth embodiment.

### DETAILED DESCRIPTION

With reference to the drawings, first to fifth embodiments will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Moreover, in some drawings, portions are illustrated with different dimensional relationships and proportions. The first to fifth embodiments described below merely illustrate schematically devices and methods for specifying and giving shapes to the technical idea of the present invention, and the span of the technical idea is not limited to materials, shapes, structures, and relative positions of elements described herein.

A “first main electrode” in the present specification is assigned to any one of an emitter electrode or a collector electrode in an insulated-gate bipolar transistor (IGBT). The first main electrode is assigned to any one of a source electrode or a drain electrode in a field-effect transistor (FET) or a static induction transistor (SIT). The first main electrode is assigned to any one of an anode electrode or a cathode electrode in a static induction (SI) thyristor, a gate turn-off (GTO) thyristor or a diode. A “second main electrode” is assigned to any one of the emitter electrode or the collector electrode in the IGBT, which is not assigned as the first main electrode. The second main electrode is assigned to any one of the source electrode or the drain electrode in the FET or the SIT, which is not assigned as the first main electrode. The second main electrode is assigned to any one of the anode electrode or the cathode electrode in the SI thyristor, the GTO thyristor or the diode, which is not assigned as the first main electrode. That is, when the “first main electrode” is the source electrode, the “second main electrode” means the drain electrode. When the “first main electrode” is the emitter electrode, the “second main electrode” means the collector electrode. When the “first main electrode” is the anode electrode, the “second main electrode” means the cathode electrode.

Additionally, definitions of directions such as “upper”, “lower”, “upper and lower”, “left”, “right”, and “left and right” in the present specification are simply definitions for convenience of description, and do not limit the technological concept of the present invention. For example, when observing an object rotated by 90 degrees, the “upper and lower” is converted to “left and right” to be read, and when observing an object rotated by 180 degrees, the “upper and lower” are read reversed, which should go without saying.

### First Embodiment

A first embodiment is illustrated with a semiconductor device that is a “2-in-1” semiconductor module having functions for two power semiconductor elements.

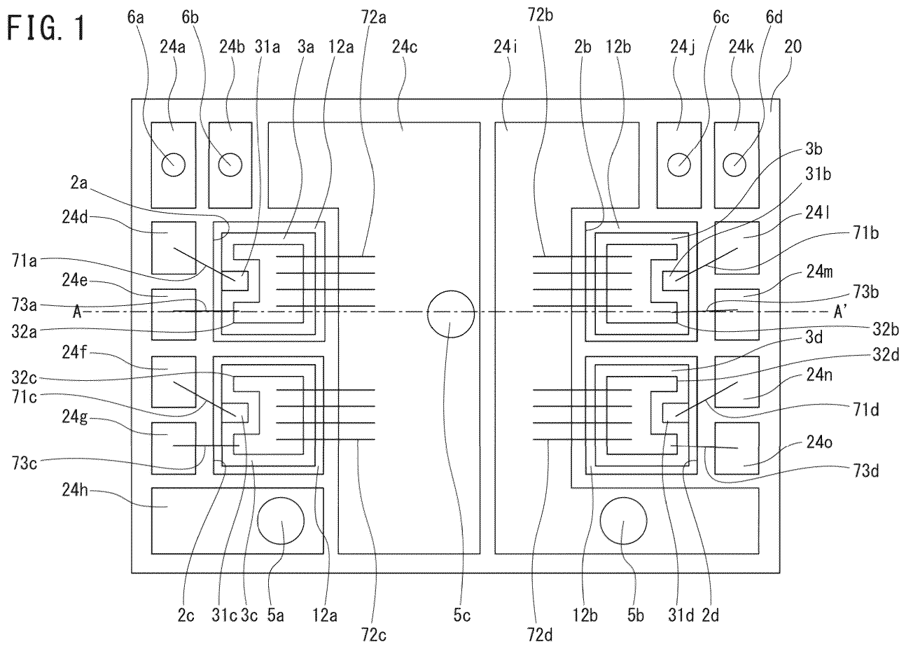

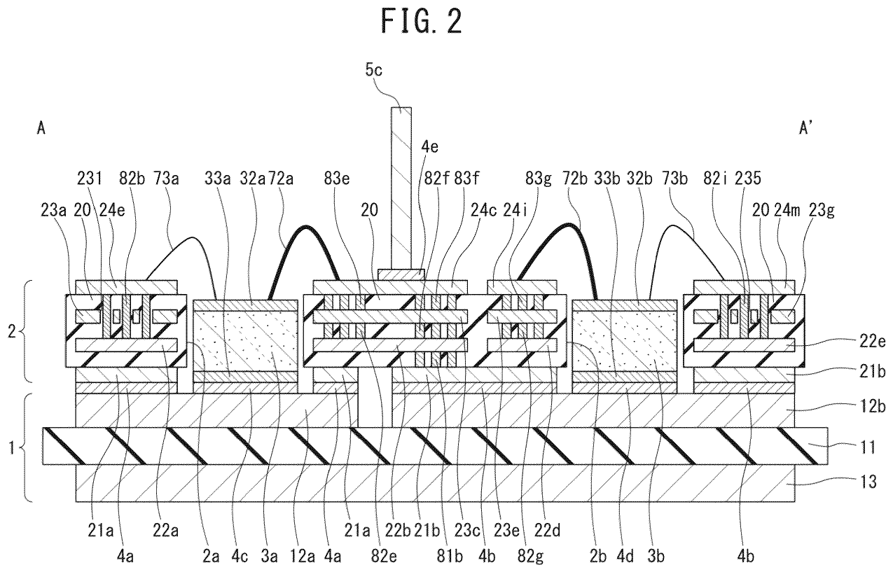

FIG. 1 is a top view illustrating the semiconductor device according to the first embodiment, and FIG. 2 is a cross-sectional view in a vertical direction taken along line A-A′ in FIG. 1. As illustrated in FIG. 1 and FIG. 2, the semiconductor device according to the first embodiment includes an insulated circuit substrate 1, power semiconductor elements (semiconductor chips) 3a to 3d provided on the top surface side of the insulated circuit substrate 1, and a printed circuit board (a multi-layer substrate) 2 provided on the top surface side of the insulated circuit substrate 1 so as to surround the side surfaces of the respective semiconductor chips 3a to 3d.

As illustrated in FIG. 2, the insulated circuit substrate 1 includes an insulating substrate 11, conductive plates (circuit plates) 12a and 12b provided separately from each other on the top surface of the insulating substrate 11, and a conductive plate (a heat-releasing plate) 13 deposited on the bottom surface of the insulating substrate 11. The insulated circuit substrate 1 may be a direct copper bonded (DCB) substrate or an active metal brazed (AMB) substrate, for example. The insulating substrate 11 is a ceramic substrate including aluminum oxide (Al₂O₃), aluminum nitride (AlN), silicon nitride (Si₃N₄), or boron nitride (BN), or a resin insulating substrate including polymer material, for example. The circuit plates 12a and 12b and the heat-releasing plate 13 each have a substantially rectangular planar pattern. Further, the circuit plates 12a and 12b and the heat-releasing plate 13 each include conductive material such as conductive foil including copper (Cu) or aluminum (Al), for example.

As illustrated in FIG. 2, the semiconductor chip 3a on the upper-arm side is bonded to the top surface of the circuit plate 12a via bonding material 4c such as solder or sintered material or by use of direct bonding means. The semiconductor chip 3b on the lower-arm side is bonded to the top surface of the circuit plate 12b via bonding material 4d such as solder or sintered material or by use of direct bonding means. The semiconductor chip 3c on the upper-arm side illustrated in FIG. 1 is also bonded to the top surface of the circuit plate 12a via bonding material such as solder or sintered material or by use of direct bonding means in the same manner as the semiconductor chip 3a. The semiconductor chip 3d on the lower-arm side is bonded to the top surface of the circuit plate 12b via bonding material such as solder or sintered material or by use of direct bonding means in the same manner as the semiconductor chip 3b.

The respective semiconductor chips 3a to 3d may include silicon (Si), or may include wide bandgap semiconductor material such as silicon carbide (SiC), gallium nitride (GaN), gallium oxide (Ga₂O₃), or diamond (C). The respective semiconductor chips 3a to 3d as used herein can be a power semiconductor element such as a field-effect transistor (FET), an insulated gate bipolar transistor (IGBT), a static induction (SI) thyristor, or a gate turn-off (GTO) thyristor, or a rectifying element such as a free-wheeling diode (FWD), for example, which may be determined depending on the intended use. The semiconductor device according to the first embodiment is illustrated below with a case in which the semiconductor chips 3a to 3d are each a MOSFET.

While FIG. 1 and FIG. 2 illustrate the case of including the four semiconductor chips 3a to 3d, the number of the semiconductor chips to be provided is not limited to this case, and can be determined as appropriate depending on a rated current, for example. As illustrated in FIG. 1 and FIG. 2, the semiconductor chip 3a includes a source electrode 32a that is a first main electrode (a top-surface electrode) and a gate electrode 31a that is a control electrode each provided on the top surface side, and a drain electrode 33a that is a second main electrode (a bottom-surface electrode) provided on the bottom surface side. The semiconductor chip 3b includes a source electrode 32b that is a first main electrode (a top-surface electrode) and a gate electrode 31b that is a control electrode each provided on the top surface side, and a drain electrode 33b that is a second main electrode (a bottom-surface electrode) provided on the bottom surface side.

The semiconductor chip 3c illustrated in FIG. 1 includes a source electrode 32c that is a first main electrode (a top-surface electrode) and a gate electrode 31c that is a control electrode each provided on the top surface side, and a drain electrode (not illustrated) that is a second main electrode (a bottom-surface electrode) provided on the bottom surface side. The semiconductor chip 3d illustrated in FIG. 1 includes a source electrode 32d that is a first main electrode (a top-surface electrode) and a gate electrode 31d that is a control electrode each provided on the top surface side, and a drain electrode (not illustrated) that is a second main electrode (a bottom-surface electrode) provided on the bottom surface side.

As illustrated in FIG. 1 and FIG. 2, the printed circuit board 2 is arranged across the top surfaces of the respective circuit plates 12a and 12b of the insulated circuit substrate 1. The printed circuit board 2 includes a plurality of wiring layers 21a, 21b, 22a, 22b, 22d, 22e, 23a, 23c, 23e, 23g, and 24a to 24o electrically connected to each other through vias (connection members) such as filled vias so as to electrically connect the source electrodes 32a and 32c of the semiconductor chips 3a and 3c to the drain electrodes 33d of the semiconductor chips 3b and 3d, and an insulating layer 20 interposed between the respective wiring layers 21a, 21b, 22a, 22b, 22d, 22e, 23a, 23c, 23e, 23g, and 24a to 24o electrically connected to each other.

The wiring layers (the first wiring layers) 21a and 21b, among the plural wiring layers 21a, 21b, 22a, 22b, 22d, 22e, 23a, 23c, 23e, 23g, and 24a to 24o, that are the first and lowermost layers from the bottom are bonded to the insulated circuit substrate 1.

The wiring layers (the second wiring layers) 22a, 22b, 22d, and 22e, among the plural wiring layers 21a, 21b, 22a, 22b, 22d, 22e, 23a, 23c, 23e, 23g, and 24a to 24o, that are the second layers from the bottom are provided on the top surface side of the first wiring layers 21a and 21b with the insulating layer 20 interposed. The second wiring layers 22a, 22b, 22d, and 22e implement, for example, a main circuit through which a main current flows or a control circuit for controlling the respective semiconductor chips 3a to 3d.

The wiring layers (the third wiring layers) 23a, 23c, 23e, and 23g, among the plural wiring layers 21a, 21b, 22a, 22b, 22d, 22e, 23a, 23c, 23e, 23g, and 24a to 24o, that are the third layers from the bottom are provided on the top surface side of the second wiring layers 22a, 22b, 22d, and 22e with the insulating layer 20 interposed. The third wiring layers 23a, 23c, 23e, and 23g implement, for example, a main circuit through which a main current flows or a control circuit for controlling the respective semiconductor chips 3a to 3d.

The wiring layers (the fourth wiring layers) 24a to 24o, among the plural wiring layers 21a, 21b, 22a, 22b, 22d, 22e, 23a, 23c, 23e, 23g, and 24a to 24o, that are the fourth and uppermost layers from the bottom are provided on the top surface side of the third wiring layers 23a, 23c, 23e, and 23g with the insulating layer 20 interposed. The fourth wiring layers 24a to 24o are provided with connection regions (bonding areas) for connection members such as bonding wires connected to the semiconductor chips 3a to 3d, while external connection terminals and the like for connection to an external circuit are mounted on the fourth wiring layers 24a to 24o.

The insulating layer 20 includes insulating material such as ceramic or resin mainly containing alumina (Al₂O₃), aluminum nitride (AlN), and silicon nitride (Si₃N4), for example. The insulating layer 20 may include other insulating material such as polyimide resin or a combination of glass fiber and epoxy resin.

The first wiring layers 21a and 21b, the second wiring layers 22a, 22b, 22d, and 22e, the third wiring layers 23a, 23c, 23e, and 23g, and the fourth wiring layers 24a to 24o include conductive material such as copper (Cu), a Cu alloy mainly containing Cu, aluminum (Al), and an Al alloy mainly containing Al, for example.

As illustrated in FIG. 2, the first wiring layers 21a and 21b are bonded to the circuit plates 12a and 12b of the insulated circuit substrate 1. The first wiring layer 21a is bonded to the circuit plate 12a via bonding material 4a such as solder or sintered material or by use of direct bonding means. The first wiring layer 21b is bonded to the circuit plate 12b via bonding material 4b such as solder or sintered material or by use of direct bonding means. The respective top surfaces of the first wiring layers 21a and 21b are bonded to the insulating layer 20.

As illustrated in FIG. 2, the second wiring layers 22a, 22b, 22d, and 22e are buried inside the insulating layer 20. The second wiring layer 22a is located above to partly overlap with the first wiring layer 21a with the insulating layer 20 interposed. The second wiring layer 22b is located above to partly overlap with each of the first wiring layer 21a and the first wiring layer 21b with the insulating layer 20 interposed. The second wiring layer 22b is electrically connected to the first wiring layer 21b through vias 81b penetrating through-holes provided in the insulating layer 20. The second wiring layer 22d is located above to partly overlap with the first wiring layer 21b with the insulating layer 20 interposed. The second wiring layer 22e is located above to partly overlap with the first wiring layer 21b with the insulating layer 20 interposed.

As illustrated in FIG. 2, the third wiring layers 23a, 23c, 23e, and 23g are buried inside the insulating layer 20. The third wiring layer 23a is located above to overlap with the second wiring layer 22a with the insulating layer 20 interposed. The third wiring layer 23a is provided with through-holes 231. The third wiring layer 23c is located above to overlap with the second wiring layer 22b with the insulating layer 20 interposed. The third wiring layer 23c is electrically connected to the second wiring layer 22b through vias 82e and 82f penetrating through-holes provided in the insulating layer 20. The third wiring layer 23e is located above to overlap with the second wiring layer 22d with the insulating layer 20 interposed. The third wiring layer 23e is electrically connected to the second wiring layer 22d through vias 82g penetrating through-holes provided in the insulating layer 20. The third wiring layer 23g is located above to overlap with the second wiring layer 22e with the insulating layer 20 interposed. The third wiring layer 23g is provided with through-holes 235.

As illustrated in FIG. 2, the fourth wiring layers 24e, 24c, 24i, and 24m are bonded to the insulating layer 20 on the top surface side. The fourth wiring layer 24e is located above to overlap with the third wiring layer 23a with the insulating layer 20 interposed. The fourth wiring layer 24e is electrically connected to the second wiring layer 22a through through-holes provided in the insulating layer 20 and through vias 82b penetrating the through-holes 231 provided in the third wiring layer 23a. The fourth wiring layer 24c is located above to overlap with the third wiring layer 23c with the insulating layer 20 interposed. The fourth wiring layer 24c is electrically connected to the third wiring layer 23c through vias 83e and 83f penetrating through-holes provided in the insulating layer 20.

The fourth wiring layer 24i is located above to overlap with the third wiring layer 23e with the insulating layer 20 interposed. The fourth wiring layer 24i is electrically connected to the third wiring layer 23e through vias 83g penetrating through-holes provided in the insulating layer 20. The fourth wiring layer 24m is located above to overlap with the third wiring layer 23g with the insulating layer 20 interposed. The fourth wiring layer 24m is electrically connected to the second wiring layer 22e through through-holes provided in the insulating layer 20 and vias 82i penetrating the through-holes 235 provided in the third wiring layer 23g.

As illustrated in FIG. 1, the insulating layer 20 is provided with openings 2a to 2d to surround the outer circumferences (the side surfaces) of the semiconductor chips 3a to 3d. The respective openings 2a to 2d penetrate the insulating layer 20 from the top surface to the bottom surface. The respective top surfaces of the semiconductor chips 3a to 3d are exposed to the outside through the openings 2a to 2d. The fourth wiring layers 24a to 24o are provided along the regions in which the semiconductor chips 3a to 3d are mounted and in which the openings 2a to 2d of the insulating layer 20 are provided.

A lower end of a control terminal (a gate control terminal) 6a that is an external connection terminal is bonded to the fourth wiring layer 24a via bonding material such as solder or sintered material or by use of direct bonding means. The gate control terminal 6a extends upward from the fourth wiring layer 24a. The upper end of the gate control terminal 6a is connected to an external circuit (not illustrated). The gate control terminal 6a is electrically connected to the gate electrodes 31a and 31c of the semiconductor chips 3a and 3c. The gate control terminal 6a applies control signals to the gate electrodes 31a and 31c of the semiconductor chips 3a and 3c so as to control ON-OFF operations of the semiconductor chips 3a and 3c.

A lower end of a control terminal (an auxiliary source terminal) 6b that is an external connection terminal is bonded to the fourth wiring layer 24b via bonding material such as solder or sintered material or by use of direct bonding means. The auxiliary source terminal 6b extends upward from the fourth wiring layer 24b. The upper end of the auxiliary source terminal 6b is connected to an external circuit (not illustrated). The auxiliary source terminal 6b is electrically connected to the source electrodes 32a and 32c of the semiconductor chips 3a and 3c. The auxiliary source terminal 6b detects current flowing through the respective semiconductor chips 3a and 3c.

The source electrode 32a of the semiconductor chip 3a is connected to the fourth wiring layer 24c via a bonding wire 72a that is a connection member. The source electrode 32c of the semiconductor chip 3c is also connected to the fourth wiring layer 24c via bonding wires 72a that are connection members.

As illustrated in FIG. 1 and FIG. 2, a lower end of an output terminal 5c that is an external connection terminal is bonded to the fourth wiring layer 24c via bonding material 4e such as solder or sintered material or by use of direct bonding means. The output terminal 5c extends upward above the insulated circuit substrate 1. The upper end of the output terminal 5c is connected to an external circuit (not illustrated). The output terminal 5c is electrically connected to the source electrodes 32a and 32c of the semiconductor chips 3a and 3c and the drain electrodes 33b of the semiconductor chips 3b and 3d. The output terminal 5c leads current from the source electrodes 32a and 32c of the semiconductor chips 3a and 3c to flow through the external circuit when the semiconductor chips 3a and 3c are in the ON state. Further, the output terminal 5c supplies the current from the external circuit to the drain electrodes 33b of the semiconductor chips 3b and 3d when in the ON state.

As illustrated in FIG. 1, the gate electrode 31a of the semiconductor chip 3a is connected to the fourth wiring layer 24d via a bonding wire 71a that is a connection member. The source electrode 32a of the semiconductor chip 3a is connected to the fourth wiring layer 24e via a bonding wire 73a that is a connection member. The gate electrode 31c of the semiconductor chip 3c is connected to the fourth wiring layer 24f via a bonding wire 71c that is a connection member. The source electrode 32c of the semiconductor chip 3c is connected to the fourth wiring layer 24g via a bonding wire 73c that is a connection member.

A lower end of a positive-electrode terminal (a P terminal) 5a that is an external connection terminal on the high-potential side is bonded to the fourth wiring layer 24h via bonding material such as solder or sintered material or by use of direct bonding means. The P terminal 5a extends upward above the fourth wiring layer 24h. The upper end of the P terminal 5a is connected to an external circuit (not illustrated). The P terminal 5a is electrically connected to the drain electrodes 33a of the semiconductor chips 3a and 3c. The P terminal 5a supplies current to the drain electrodes 33a of the semiconductor chips 3a and 3c through the external circuit.

The source electrode 32b of the semiconductor chip 3b is connected to the fourth wiring layer 24i via bonding wires 72b that are connection members. The source electrode 32d of the semiconductor chip 3d is also connected to the fourth wiring layer 24i via bonding wires 72d that are connection members.

A lower end of a negative-electrode terminal (an N terminal) 5b that is an external connection terminal on the low-potential side is bonded to the fourth wiring layer 24i via bonding material such as solder or sintered material or by use of direct bonding means. The N terminal 5b extends upward above the fourth wiring layer 24i. The upper end of the N terminal 5b is connected to an external circuit (not illustrated). The N terminal 5b is electrically connected to the source electrodes 32b and 32d of the semiconductor chips 3b and 3d. The N terminal 5b leads current from the source electrodes 32b and 32d of the semiconductor chips 3b and 3d to flow through the external circuit.

A lower end of a control terminal (an auxiliary source terminal) 6c that is an external connection terminal is bonded to the fourth wiring layer 24j via bonding material such as solder or sintered material or by use of direct bonding means. The auxiliary source terminal 6c extends upward above the fourth wiring layer 24j. The upper end of the auxiliary source terminal 6c is connected to an external circuit (not illustrated). The auxiliary source terminal 6c is electrically connected to the source electrodes 32b and 32d of the semiconductor chips 3b and 3d. The auxiliary source terminal 6c detects current flowing through the semiconductor chips 3b and 3d.

A lower end of a control terminal (a gate control terminal) 6d that is an external connection terminal is bonded to the fourth wiring layer 24k via bonding material such as solder or sintered material or by use of direct bonding means. The gate control terminal 6d extends upward above the fourth wiring layer 24k. The upper end of the gate control terminal 6d is connected to an external circuit (not illustrated). The gate control terminal 6d is electrically connected to the gate electrodes 31b and 31d of the semiconductor chips 3b and 3d. The gate control terminal 6d applies control signals to the gate electrodes 31b and 31d of the semiconductor chips 3b and 3d so as to control ON-OFF operations of the semiconductor chips 3b and 3d.

The gate electrode 31b of the semiconductor chip 3b is connected to the fourth wiring layer 24l via a bonding wire 71b that is a connection member. The source electrode 32b of the semiconductor chip 3b is connected to the fourth wiring layer 24m via a bonding wire 73b that is a connection member. The gate electrode 31d of the semiconductor chip 3d is connected to the fourth wiring layer 24h via a bonding wire 71d that is a connection member. The source electrode 32d of the semiconductor chip 3d is connected to the fourth wiring layer 24o via a bonding wire 73d that is a connection member.

The bonding wires 71a to 71d, 72a to 72d, and 73a to 73d illustrated in FIG. 1 and FIG. 2 that are the connection members each include conductive material such as aluminum (Al), for example. The thickness and the number of the respective bonding wires 71a to 71d, 72a to 72d, and 73a to 73d are not limited to the case as illustrated, and can be changed as appropriate.

The gate control terminals 6a and 6d, the auxiliary source terminals 6b and 6c, the P terminal 5a, the N terminal 5b, and the output terminal 5c include conductive material such as copper (Cu), a Cu alloy mainly containing Cu, aluminum (Al), and an Al alloy mainly containing Al, for example. The gate control terminals 6a and 6d, the auxiliary source terminals 6b and 6c, the P terminal 5a, the N terminal 5b, and the output terminal 5c may include either the same material or different kinds of material.

While FIG. 1 and FIG. 2 illustrate the case in which the gate control terminals 6a and 6d, the auxiliary source terminals 6b and 6c, the P terminal 5a, the N terminal 5b, and the output terminal 5c each have a cylindrical or stick-like shape, the respective terminals may have a polygonal square columnar shape or a plate-like shape. The gate control terminals 6a and 6d and the auxiliary source terminals 6b and 6c may have a smaller thickness than the P terminal 5a, the N terminal 5b, and the output terminal 5c.

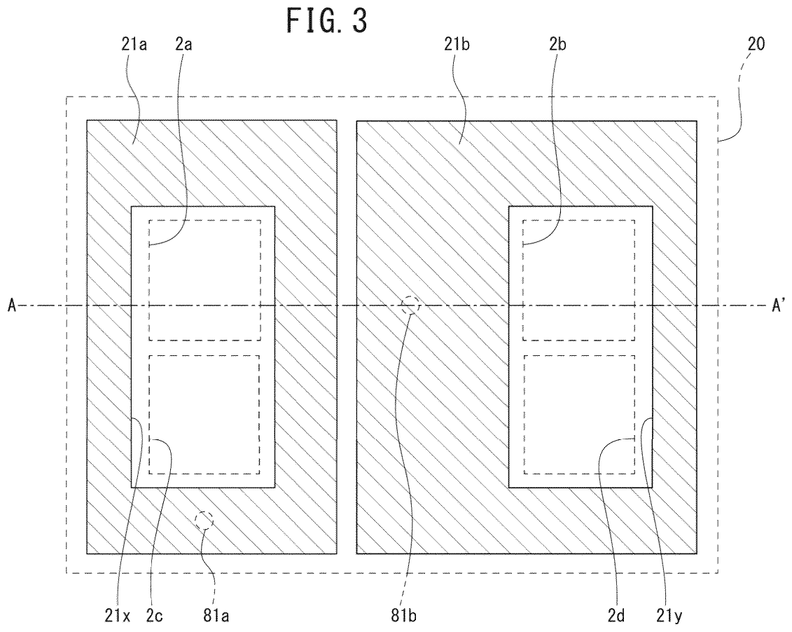

FIG. 3 is a cross-sectional view of the printed circuit board 2 in the horizontal direction passing through the first wiring layers 21a and 21b. FIG. 3 schematically indicates, by the broken lines, the insulating layer 20 on the top surface side of the first wiring layers 21a and 21b and the vias 81a and 81b connected to the top surface side of the first wiring layers 21a and 21b. As illustrated in FIG. 3, the first wiring layers 21a and 21b are provided separately from each other.

The first wiring layer 21a has an outline with a rectangular planar pattern. The first wiring layer 21a is provided with an opening 21x collectively surrounding the respective openings 2a and 2c of the insulating layer 20. The via 81a is connected to the top surface side of the first wiring layer 21a. The number and the connected position of the via 81a may be changed as appropriate.

The first wiring layer 21b has an outline with a rectangular planar pattern. The first wiring layer 21b is provided with an opening 21y collectively surrounding the respective openings 2b and 2d of the insulating layer 20. The via 81b is connected to the top surface side of the first wiring layer 21b. The number and the connected position of the via 81b may be changed as appropriate.

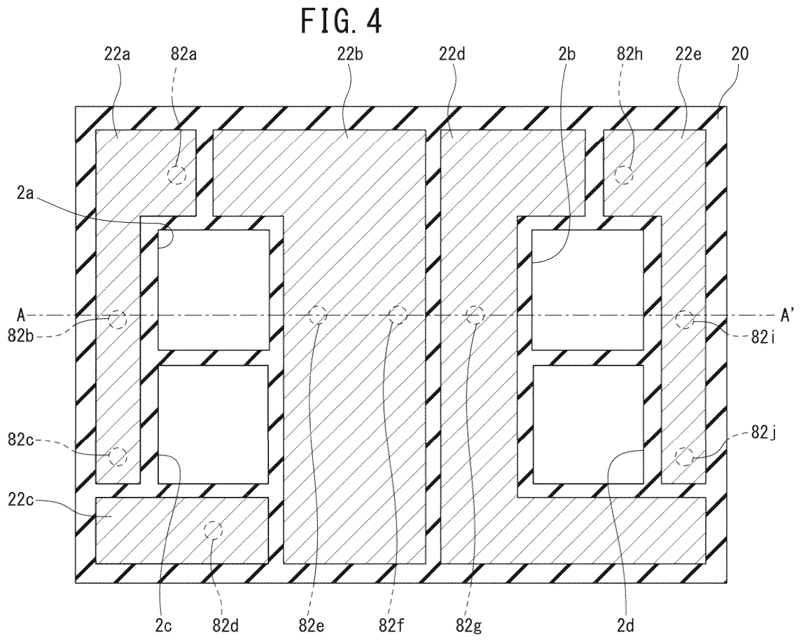

FIG. 4 is a cross-sectional view of the printed circuit board 2 in the horizontal direction passing through the second wiring layers 22a to 22e. FIG. 4 schematically indicates, by the broken lines, the vias 82a to 82j connected to the top surface side of the second wiring layers 22a to 22e. As illustrated in FIG. 4, the second wiring layers 22a to 22e are provided separately from each other with the insulating layer 20 interposed.

The second wiring layer 22a has an L-shaped planar pattern. The second wiring layer 22a is located above to partly overlap with the first wiring layer 21a illustrated in FIG. 3 with the insulating layer 20 interposed. The vias 82a to 82c are connected to the top surface side of the second wiring layer 22a. The number and the connected positions of the vias 82a to 82c may be changed as appropriate. While FIG. 4 indicates the single via 82b, FIG. 2 illustrates the case of including the three vias 82b.

The second wiring layer 22b has an L-shaped planar pattern. The second wiring layer 22b is located above and across to partly overlap with the respective first wiring layers 21a and 21b illustrated in FIG. 3 with the insulating layer 20 interposed. The via 81b illustrated in FIG. 3 is connected to the bottom surface of the second wiring layer 22b. The provision of the via 81b leads the second wiring layer 22b and the first wiring layer 21b to be electrically connected to each other. The vias 82e and 82f are connected to the top surface of the second wiring layer 22b. The number and the connected positions of the vias 82e to 82f may be changed as appropriate. While FIG. 4 indicates the single via 82e and the single via 82f, FIG. 2 illustrates the case of including the respective three vias 82e and 82f.

The second wiring layer 22c has a rectangular planar pattern. The second wiring layer 22c is located above to partly overlap with the first wiring layer 21a illustrated in FIG. 3. The via 81a illustrated in FIG. 3 is connected to the bottom surface of the second wiring layer 22c. The provision of the via 81a leads the second wiring layer 22c and the first wiring layer 21a to be electrically connected to each other. The via 82d is connected to the upper side of the second wiring layer 22c. The number and the connected position of the via 82d may be changed as appropriate.

The second wiring layer 22d has a U-shaped planar pattern. The second wiring layer 22d is located above to partly overlap with the first wiring layer 21b illustrated in FIG. 3. The via 82g is connected to the upper side of the second wiring layer 22d. The number and the connected position of the via 82g may be changed as appropriate. While FIG. 4 indicates the single via 82g, FIG. 2 illustrates the case of including the three vias 82g.

The second wiring layer 22e has an L-shaped planar pattern. The second wiring layer 22e is located above to partly overlap with the first wiring layer 21b illustrated in FIG. 3 with the insulating layer 20 interposed. The vias 82h to 82j are connected to the upper side of the second wiring layer 22e. The number and the connected positions of the vias 82h to 82j may be changed as appropriate. While FIG. 4 indicates the single via 82i, FIG. 2 illustrates the case of including the three vias 82i.

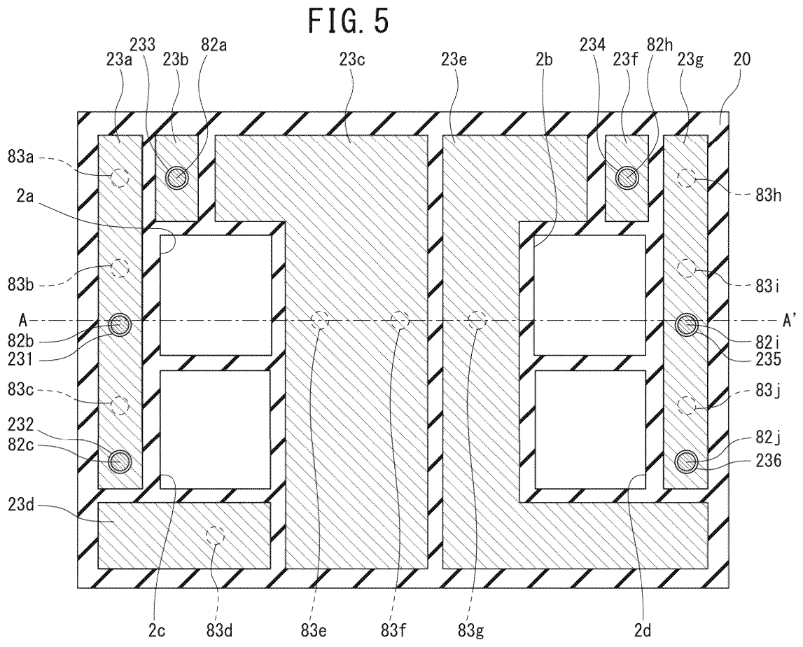

FIG. 5 is a cross-sectional view of the printed circuit board 2 in the horizontal direction passing through the third wiring layers 23a to 23g. FIG. 5 schematically indicates, by the broken lines, the vias 83a to 83j connected to the top surface side of the third wiring layers 23a to 23g. As illustrated in FIG. 5, the third wiring layers 23a to 23g are provided separately from each other with the insulating layer 20 interposed.

The third wiring layer 23a has a rectangular planar pattern. The third wiring layer 23a is located above to partly overlap with the second wiring layer 22a illustrated in FIG. 4 with the insulating layer 20 interposed. The third wiring layer 23a is provided with the through-holes 231 and 232 through which the vias 82b and 82c penetrate. The vias 83a to 83c are connected to the top surface side of the third wiring layer 23a. The number and the connected positions of the vias 83a to 83c may be changed as appropriate.

The third wiring layer 23b has a rectangular planar pattern. The third wiring layer 23b is located above to partly overlap with the second wiring layer 22a illustrated in FIG. 4 with the insulating layer 20 interposed. The third wiring layer 23b is provided with a through-hole 233 through which the via 82a penetrates.

The third wiring layer 23c has an L-shaped planar pattern. The third wiring layer 23c is located above to overlap with the second wiring layer 22b illustrated in FIG. 4 with the insulating layer 20 interposed. The vias 82e and 82f illustrated in FIG. 4 are connected to the bottom surface side of the third wiring layer 23c. The provision of the vias 82e and 82f leads the third wiring layer 23c and the second wiring layer 22b to be electrically connected to each other. The vias 83e and 83f are connected to the top surface side of the third wiring layer 23c. The number and the connected positions of the vias 83e and 83f may be changed as appropriate. While FIG. 5 indicates the single via 83e and the single via 83f, FIG. 2 illustrates the case of including the respective three vias 83e and 83f.

The third wiring layer 23d has a rectangular planar pattern. The third wiring layer 23d is located above to overlap with the second wiring layer 22c illustrated in FIG. 4 with the insulating layer 20 interposed. The via 82d illustrated in FIG. 4 is connected to the bottom surface side of the third wiring layer 23d. The provision of the via 82d leads the third wiring layer 23d and the second wiring layer 22c to be electrically connected to each other. The via 83d is connected to the top surface side of the third wiring layer 23d. The number and the connected position of the via 83d may be changed as appropriate.

The third wiring layer 23e has a U-shaped planar pattern. The third wiring layer 23e is located above to overlap with the second wiring layer 22d illustrated in FIG. 4 with the insulating layer 20 interposed. The via 82g illustrated in FIG. 4 is connected to the bottom surface side of the third wiring layer 23e. The provision of the via 82g leads the third wiring layer 23e and the second wiring layer 22d to be electrically connected to each other. The via 83g is connected to the top surface side of the third wiring layer 23e. The number and the connected position of the via 83g may be changed as appropriate. While FIG. 5 indicates the single via 83g, FIG. 2 illustrates the case of including the three vias 83g.

The third wiring layer 23f has a rectangular planar pattern. The third wiring layer 23f is located above to partly overlap with the second wiring layer 22e illustrated in FIG. 4 with the insulating layer 20 interposed. The third wiring layer 23f is provided with a through-hole 234 through which the via 82h penetrates.

The third wiring layer 23g has a rectangular planar pattern. The third wiring layer 23g is located above to partly overlap with the second wiring layer 22e illustrated in FIG. 4 with the insulating layer 20 interposed. The third wiring layer 23g is provided with through-holes 235 and 236 through which the vias 82i and 82j penetrate. The vias 83h to 83j are connected to the top surface side of the third wiring layer 23g. The number and the connected positions of the vias 83h to 83j may be changed as appropriate.

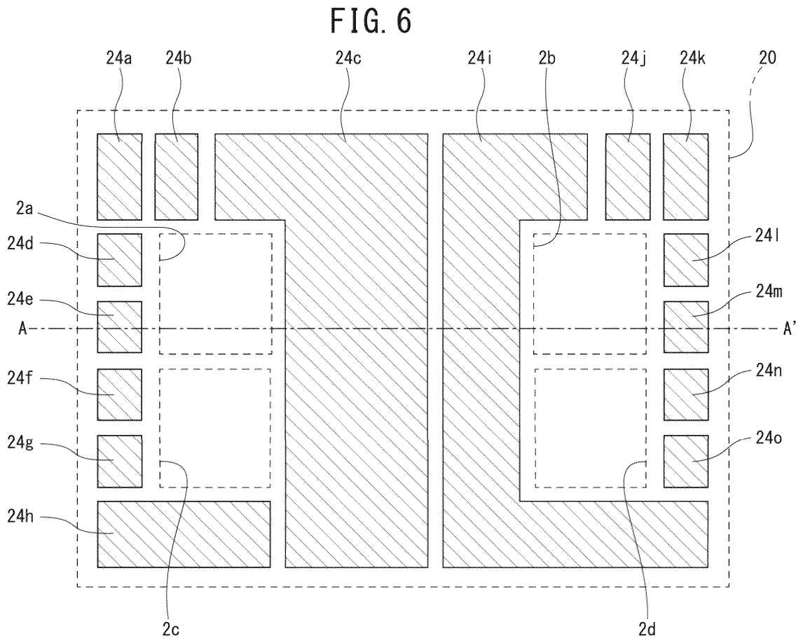

FIG. 6 is a cross-sectional view of the printed circuit board 2 in the horizontal direction passing through the fourth wiring layers 24a to 24o. FIG. 6 schematically indicates, by the broken lines, the insulating layer 20 on the bottom surface side of the fourth wiring layers 24a to 24o. As illustrated in FIG. 6, the fourth wiring layers 24a to 24o are provided separately from each other.

The fourth wiring layer 24a has a rectangular planar pattern. The fourth wiring layer 24a is located above to partly overlap with the third wiring layer 23a illustrated in FIG. 5 with the insulating layer 20 interposed. The via 83a illustrated in FIG. 5 is connected to the bottom surface side of the fourth wiring layer 24a. The provision of the via 83a leads the fourth wiring layer 24a and the third wiring layer 23a to be electrically connected to each other.

The fourth wiring layer 24b has a rectangular planar pattern. The fourth wiring layer 24b is located above to overlap with the third wiring layer 23b illustrated in FIG. 5 with the insulating layer 20 interposed. The via 82a illustrated in FIG. 5 is connected to the bottom surface side of the fourth wiring layer 24b. The provision of the via 82a leads the fourth wiring layer 24b and the second wiring layer 22a to be electrically connected to each other.

The fourth wiring layer 24c has an L-shaped planar pattern. The fourth wiring layer 24c is located above to overlap with the third wiring layer 23c illustrated in FIG. 5 with the insulating layer 20 interposed. The vias 83e and 83f illustrated in FIG. 5 are connected to the bottom surface side of the fourth wiring layer 24c. The provision of the vias 83e and 83f leads the fourth wiring layer 24c and the third wiring layer 23c to be electrically connected to each other.

The fourth wiring layer 24d has a rectangular planar pattern. The fourth wiring layer 24d is located above to partly overlap with the third wiring layer 23a illustrated in FIG. 5 with the insulating layer 20 interposed. The via 83b illustrated in FIG. 5 is connected to the bottom surface side of the fourth wiring layer 24d. The provision of the via 83b leads the fourth wiring layer 24d and the third wiring layer 23a to be electrically connected to each other.

The fourth wiring layer 24e has a rectangular planar pattern. The fourth wiring layer 24e is located above to partly overlap with the third wiring layer 23a illustrated in FIG. 5 with the insulating layer 20 interposed. The via 82b illustrated in FIG. 5 is connected to the bottom surface side of the fourth wiring layer 24e. The provision of the via 82b leads the fourth wiring layer 24e and the second wiring layer 22a to be electrically connected to each other.

The fourth wiring layer 24f has a rectangular planar pattern. The fourth wiring layer 24f is located above to partly overlap with the third wiring layer 23a illustrated in FIG. 5 with the insulating layer 20 interposed. The via 83c illustrated in FIG. 5 is connected to the bottom surface side of the fourth wiring layer 24f. The provision of the via 83c leads the fourth wiring layer 24f and the third wiring layer 23a to be electrically connected to each other.

The fourth wiring layer 24g has a rectangular planar pattern. The fourth wiring layer 24g is located above to partly overlap with the third wiring layer 23a illustrated in FIG. 5 with the insulating layer 20 interposed. The via 82c illustrated in FIG. 5 is connected to the bottom surface side of the fourth wiring layer 24g. The provision of the via 82c leads the fourth wiring layer 24g and the second wiring layer 22a to be electrically connected to each other.

The fourth wiring layer 24h has a rectangular planar pattern. The fourth wiring layer 24h is located above to overlap with the third wiring layer 23d illustrated in FIG. 5 with the insulating layer 20 interposed. The via 83d illustrated in FIG. 5 is connected to the bottom surface side of the fourth wiring layer 24h. The provision of the via 83d leads the fourth wiring layer 24h and the third wiring layer 23d to be electrically connected to each other.

The fourth wiring layer 24i has a U-shaped planar pattern. The fourth wiring layer 24i is located above to overlap with the third wiring layer 23e illustrated in FIG. 5 with the insulating layer 20 interposed. The via 83g illustrated in FIG. 5 is connected to the bottom surface side of the fourth wiring layer 24i. The provision of the via 83g leads the fourth wiring layer 24i and the third wiring layer 23e to be electrically connected to each other.

The fourth wiring layer 24j has a rectangular planar pattern. The fourth wiring layer 24j is located above to overlap with the third wiring layer 23f illustrated in FIG. 5 with the insulating layer 20 interposed. The via 82h illustrated in FIG. 5 is connected to the bottom surface side of the fourth wiring layer 24j. The provision of the via 82h leads the fourth wiring layer 24j and the second wiring layer 22e to be electrically connected to each other.

The fourth wiring layer 24k has a rectangular planar pattern. The fourth wiring layer 24k is located above to partly overlap with the third wiring layer 23g illustrated in FIG. 5 with the insulating layer 20 interposed. The via 83h illustrated in FIG. 5 is connected to the bottom surface side of the fourth wiring layer 24k. The provision of the via 83h leads the fourth wiring layer 24k and the third wiring layer 23g to be electrically connected to each other.

The fourth wiring layer 24l has a rectangular planar pattern. The fourth wiring layer 24l is located above to partly overlap with the third wiring layer 23g illustrated in FIG. 5 with the insulating layer 20 interposed. The via 83i illustrated in FIG. 5 is connected to the bottom surface side of the fourth wiring layer 24l. The provision of the via 83i leads the fourth wiring layer 24l and the third wiring layer 23g to be electrically connected to each other.

The fourth wiring layer 24m has a rectangular planar pattern. The fourth wiring layer 24m is located above to partly overlap with the third wiring layer 23g illustrated in FIG. 5 with the insulating layer 20 interposed. The via 82i illustrated in FIG. 5 is connected to the bottom surface side of the fourth wiring layer 24m. The provision of the via 82i leads the fourth wiring layer 24m and the second wiring layer 22e to be electrically connected to each other.

The fourth wiring layer 24n has a rectangular planar pattern. The fourth wiring layer 24n is located above to partly overlap with the third wiring layer 23g illustrated in FIG. 5 with the insulating layer 20 interposed. The via 83j illustrated in FIG. 5 is connected to the bottom surface side of the fourth wiring layer 24n. The provision of the via 83j leads the fourth wiring layer 24n and the third wiring layer 23g to be electrically connected to each other.

The fourth wiring layer 24o has a rectangular planar pattern. The fourth wiring layer 24o is located above to partly overlap with the third wiring layer 23g illustrated in FIG. 5 with the insulating layer 20 interposed. The via 82j illustrated in FIG. 5 is connected to the bottom surface side of the fourth wiring layer 24o. The provision of the via 82j leads the fourth wiring layer 24o and the second wiring layer 22e to be electrically connected to each other.

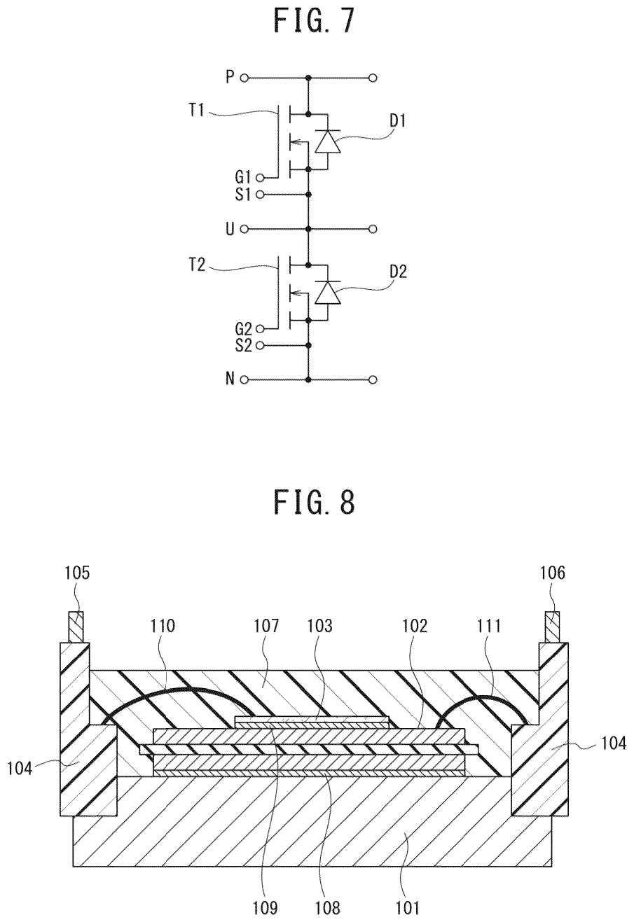

FIG. 7 is an equivalent circuit diagram of the semiconductor device according to the first embodiment. As illustrated in FIG. 7, the semiconductor device according to the first embodiment implements a part of a three-phase bridge circuit.

A drain terminal P is connected to a second main electrode (a drain electrode) of a transistor T1 on the upper-arm side, and a source terminal N is connected to a first main electrode (a source electrode) of a transistor T2 on the lower-arm side. A source electrode of the transistor T1 and a drain electrode of the transistor T2 are connected to an output terminal U and an auxiliary source terminal S1. An auxiliary source terminal S2 is connected to the source electrode of the transistor T2.

A gate control terminal G1 is connected to a gate electrode of the transistor T1. A gate control terminal G2 is connected to a gate electrode of the transistor T2. A body diode D1 serving as a freewheeling diode (FWD) is internally connected in antiparallel to the transistor T1. A body diode D2 serving as a freewheeling diode (FWD) is internally connected in antiparallel to the transistor T2.

The drain terminal P, the source terminal N, and the output terminal U illustrated in FIG. 7 respectively correspond to the P terminal 5a, the N terminal 5b, and the output terminal 5c illustrated in FIG. 1. The transistor T1 illustrated in FIG. 7 corresponds to the semiconductor chips 3a and 3c illustrated in FIG. 1. The transistor T2 illustrated in FIG. 7 corresponds to the semiconductor chips 3b and 3d illustrated in FIG. 1. The gate control terminals G1 and G2 illustrated in FIG. 7 correspond to the gate control terminals 6a and 6d illustrated in FIG. 1. The auxiliary source terminals S1 and S2 illustrated in FIG. 7 correspond to the auxiliary source terminals 6b and 6c illustrated in FIG. 1.

During the switching operation of the semiconductor device according to the first embodiment illustrated in FIG. 1 and FIG. 2, the control signals for controlling the ON-OFF operations of the semiconductor chips 3a and 3c are applied to the gate electrodes 31a and 31c of the semiconductor chips 3a and 3c through the gate control terminal 6a, and the control signals for controlling the ON-OFF operations of the semiconductor chips 3b and 3d are applied to the gate electrodes 31b and 31d of the semiconductor chips 3b and 3d through the gate control terminal 6d. This signal application leads the semiconductor chips 3a and 3c and the semiconductor chips 3b and 3d to alternately repeat the ON-OFF operations.

When the semiconductor chips 3a and 3c on the upper-arm side are in the ON state, a current entering from the P terminal 5a flows through the drain electrodes 33a of the semiconductor chips 3a and 3c via the fourth wiring layer 24h, the via 83d, the third wiring layer 23d, the via 82d, the second wiring layer 22c, the via 81a, and the first wiring layer 21a of the printed circuit board 2, and the circuit plate 12a. Further, a current from the source electrodes 32a and 32c of the semiconductor chips 3a and 3c flows through the output terminal 5c into the external circuit via the bonding wires 72a and 72c and the fourth wiring layer 24c of the printed circuit board 2.

When the semiconductor chips 3b and 3d on the lower-arm side are in the ON state, a current entering the output terminal 5c from the external circuit flows through the drain electrodes 33b of the semiconductor chips 3b and 3d on the lower-arm side via the fourth wiring layer 24i, the via 83g, the third wiring layer 23e, the via 82g, the second wiring layer 22d, the via 81d, and the first wiring layer 21b of the printed circuit board 2, and the circuit plate 12b. Further, a current from the source electrodes 32b and 32d of the semiconductor chips 3b and 3d flows through the N terminal 5b into the external circuit via the bonding wires 72b and 72d and the fourth wiring layer 24i of the printed circuit board 2.

### Method of Manufacturing Semiconductor Device

An example of a method of manufacturing (assembling) the semiconductor device according to the first embodiment is described below. First, the insulated circuit substrate 1 and the printed circuit board 2 illustrated in FIG. 1 and FIG. 2 are prepared. Next, the first wiring layers 21a and 21b that are the lowermost layers of the printed circuit board 2 are bonded to the top surface side of the circuit plates 12a and 12b of the insulated circuit substrate 1. Next, by use of the printed circuit board 2 as a jig for positioning, the semiconductor chips 3a and 3c are positioned through the openings 2a and 2c of the printed circuit board 2 so as to be bonded to the top surface side of the circuit plate 12a of the insulated circuit substrate 1. Similarly, the semiconductor chips 3b and 3d are positioned through the openings 2b and 2d of the printed circuit board 2 so as to be bonded to the top surface side of the circuit plate 12b of the insulated circuit substrate 1.

Next, as illustrated in FIG. 1, the gate control terminal 6a is bonded to the fourth wiring layer 24a that is the uppermost layer of the printed circuit board 2, the auxiliary source terminal 6b is bonded to the fourth wiring layer 24b, the output terminal 5c is bonded to the fourth wiring layer 24c, the P terminal 5a is bonded to the fourth wiring layer 24h, the N terminal 5b is bonded to the fourth wiring layer 24i, the auxiliary source terminal 6c is bonded to the fourth wiring layer 24j, and the gate control terminal 6a is bonded to the fourth wiring layer 24k.

Next, the uppermost fourth wiring layers 24d, 24l, 24f, and 24n of the printed circuit board 2 are connected to the gate electrodes 31a to 31d of the semiconductor chips 3a to 3d via the bonding wires 71a to 71d. Similarly, the uppermost fourth wiring layer 24c of the printed circuit board 2 is connected to the source electrodes 32a and 32c of the semiconductor chips 3a and 3c via the bonding wires 72a and 72c. Similarly, the uppermost fourth wiring layer 24i of the printed circuit board 2 is connected to the source electrodes 32b and 32d of the semiconductor chips 3b and 3d via the bonding wires 72b and 72d. Similarly, the uppermost fourth wiring layers 24e, 24g, 24m, and 24o of the printed circuit board 2 are connected to the source electrodes 32a to 32d of the semiconductor chips 3a to 3d via the bonding wires 73a to 73d.

Thereafter, the respective semiconductor chips 3a to 3d and the printed circuit board 2 are sealed with a sealing member as necessary. The semiconductor device according to the first embodiment illustrated in FIG. 1 and FIG. 2 is thus completed.

### First Comparative Example

A semiconductor device of a first comparative example is described below. The semiconductor device of the first comparative example has a structure in which a semiconductor chip 103 is bonded onto the top surface side of an insulated circuit substrate 102 via solder 109, as illustrated in FIG. 8. Further, a terminal case 104 and external connection terminals 105 and 106 are connected to the respective top surfaces of the insulated circuit substrate 102 and the semiconductor chip 103 via bonding wires (aluminum wires) 110 and 111. A copper base 101 is bonded to the bottom surface side of the insulated circuit substrate 102 via solder 108. The circumference of the semiconductor chip 103 is coated with gel sealing material 107.

The structure of the semiconductor device of the first comparative example needs to ensure a bonding area for the circuit formation on the top surface side of the insulated circuit substrate 102, which impedes a reduction in size of the module. In contrast, the semiconductor device according to the first embodiment has the configuration, as illustrated in FIG. 1 and FIG. 2, including the multi-layered printed circuit board 2 provided at the circumferences of the semiconductor chips 3a to 3d, so as to ensure the connection region such as the bonding area in the uppermost layer of the printed circuit board 2 and allow the circuits such as the main circuit and the control circuit to be provided in the layers different from the connection region inside the printed circuit board 2, enabling a reduction in size (high-density packaging) of the semiconductor module accordingly.

### Second Comparative Example

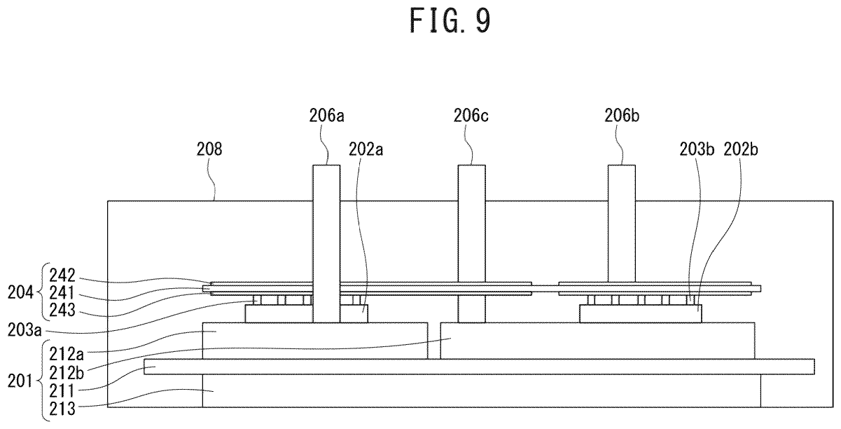

A semiconductor device of a second comparative example is described below. The semiconductor device of the second comparative example includes an insulated circuit substrate 201 including an insulating substrate 211, circuit plates 212a and 212b provided on the top surface of the insulated circuit substrate 211, and a heat-releasing plate 213 provided on the bottom surface of the insulating substrate 211, as illustrated in FIG. 9. Further, semiconductor chips 202a and 202b are bonded to the respective top surfaces of the circuit plates 212a and 212b.

A printed circuit board 204 is arranged over the respective semiconductor chips 202a and 202b. The semiconductor chips 202a and 202b are connected to the printed circuit board 204 via post electrodes (pin terminals) 203a and 203b. The printed circuit board 204 includes an insulating layer 241, a wiring layer 242 provided on the top surface of the insulating layer 241, and a wiring layer 243 provided on the bottom surface of the insulating layer 241. An external connection terminal 206a is bonded to the top surface of the circuit plate 212a. An external connection terminal 206b is bonded to the top surface of the wiring layer 242. An external connection terminal 206c is bonded to the top surface of the circuit plate 212b.

The structure of the semiconductor device of the second comparative example, in which the printed circuit board 204 is arranged over the respective semiconductor chips 202a and 202b so as to be connected to each other via the post electrodes 203a and 203b, can easily lead to a reduction in size, since the semiconductor device does not need to ensure any bonding area, which is required for the semiconductor device of the first comparative example. However, the components such as the semiconductor chips 202a and 202b are hidden by the printed circuit board 204 arranged over the semiconductor chips 202a and 202b. This complicates the alignment during packaging of the components and impedes an inspection of the bonded parts, which would lead to a decrease in quality. In contrast, the semiconductor device according to the first embodiment has the configuration, as illustrated in FIG. 1 and FIG. 2, in which the top surfaces of the respective semiconductor chips 3a to 3d are exposed to the openings 2a to 2d of the printed circuit board 2 as viewed from the top surface side of the semiconductor device. This configuration enables the positional recognition of the components such as the semiconductor chips 3a to 3d, so as to facilitate the alignment during the packaging of the components and the inspection of the bonded parts to avoid a decrease in quality, improving the reliability of products accordingly.

Further, the configuration of the semiconductor device according to the first embodiment can use the printed circuit board 2 itself as a jig so as to facilitate the positioning of the semiconductor chips 3a to 3d on the openings 2a to 2d of the printed circuit board 2, as compared with a conventional case which needs to position semiconductor chips by use of an additional jig such as a carbon during chip packaging. This configuration does not need to use such an extra jig such as a carbon and thus facilitate the chip packaging accordingly.

Further, the configuration of the semiconductor device according to the first embodiment, in which the printed circuit board 2 is bonded to the top surface of the insulated circuit substrate 1, can allow heat in the printed circuit board 2 to be easily transmitted to the insulated circuit substrate 1, so as to easily cool the printed circuit board 2, as compared with the case of the semiconductor device of the second comparative example in which the printed circuit board is arranged over the semiconductor chips.

Further, the semiconductor device according to the first embodiment has the configuration in which the third wiring layer 23a illustrated in FIG. 5 electrically connected to the gate control terminal 6a is arranged to be opposed to the second wiring layer 22a illustrated in FIG. 4 electrically connected to the auxiliary source terminal 6b with the insulating layer 20 interposed, and the third wiring layer 23g illustrated in FIG. 5 electrically connected to the gate control terminal 6d is arranged to be opposed to the second wiring layer 22e illustrated in FIG. 4 electrically connected to the auxiliary source terminal 6c with the insulating layer 20 interposed. This configuration causes the current to flow through the third wiring layer 23a and the second wiring layer 22a and through the third wiring layer 23g and the second wiring layer 22e in the opposite directions, so as to reduce the wiring inductance.

### Second Embodiment

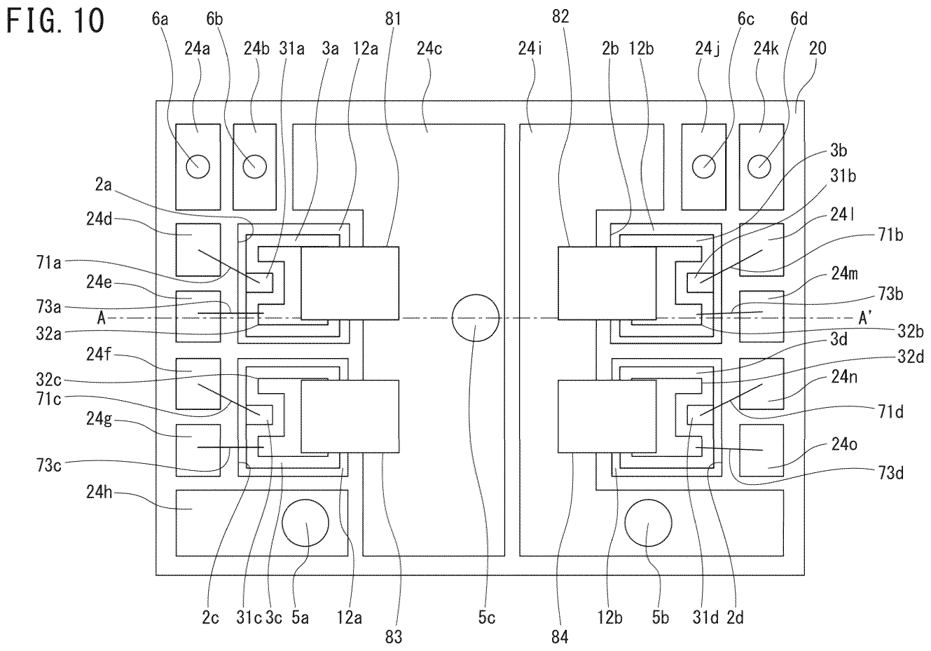

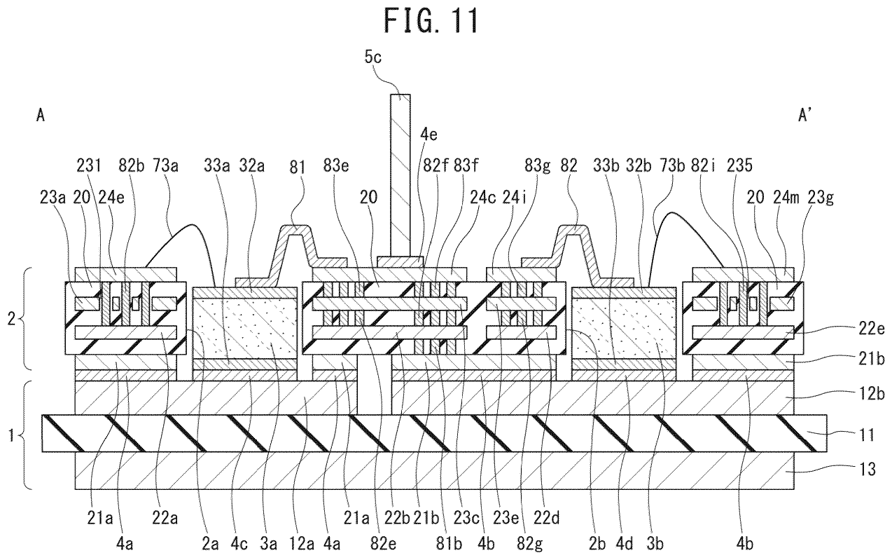

FIG. 10 is a top view illustrating a semiconductor device according to a second embodiment, and FIG. 11 is a cross-sectional view in the vertical direction taken along line A-A′ in FIG. 10. As illustrated in FIG. 10 and FIG. 11, the semiconductor device according to the second embodiment differs from the semiconductor device according to the first embodiment illustrated in FIG. 1 and FIG. 2 in that the source electrodes 32a and 32c of the semiconductor chips 3a and 3c are connected to the fourth wiring layer 24c of the printed circuit board 2 via lead frames 81 and 83 that are connection members, and the source electrodes 32b and 32d of the semiconductor chips 3b and 3d are connected to the fourth wiring layer 24i of the printed circuit board 2 via lead frames 82 and 84.

One end of the lead frame 81 is bonded to the source electrode 32a of the semiconductor chip 3a, and the other end is bonded to the fourth wiring layer 24c. One end of the lead frame 82 is bonded to the source electrode 32b of the semiconductor chip 3b, and the other end is bonded to the fourth wiring layer 24i. One end of the lead frame 83 is bonded to the source electrode 32c of the semiconductor chip 3c, and the other end is bonded to the fourth wiring layer 24c. One end of the lead frame 84 is bonded to the source electrode 32d of the semiconductor chip 3d, and the other end is bonded to the fourth wiring layer 24i. The other configurations of the semiconductor device according to the second embodiment are substantially the same as those of the semiconductor device according to the first embodiment, and overlapping explanations are not repeated below.

The configuration of the semiconductor device according to the second embodiment as described above enables a reduction in size (high-density packaging) of the semiconductor module, and can also facilitate the alignment during the packaging of the components and the inspection of the bonded parts, so as to avoid a decrease in quality of products, as in the case of the semiconductor device according to the first embodiment. Further, the use of the lead frames 81 to 84 that are the connection members can improve the reliability of the device.

### Third Embodiment

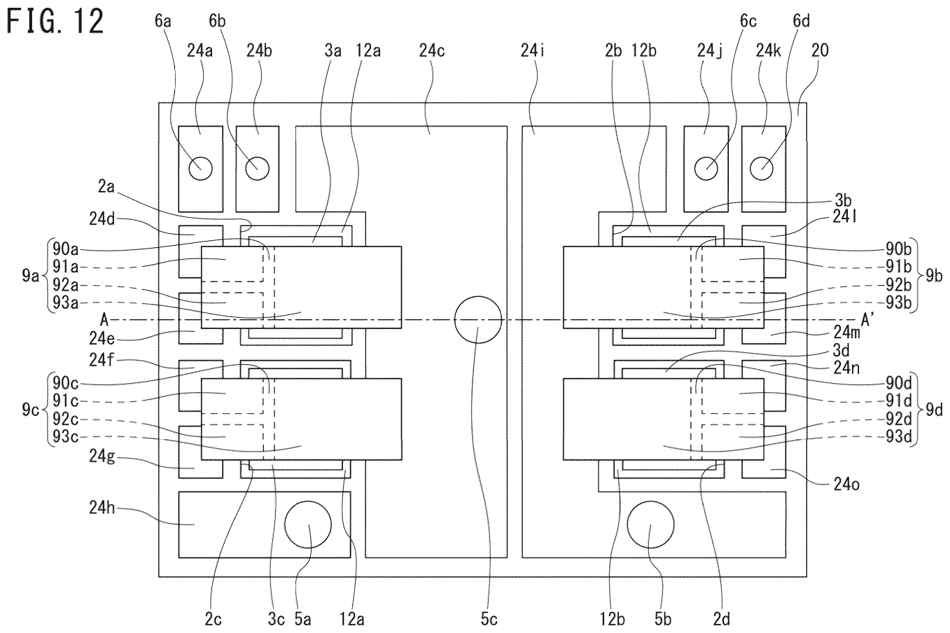

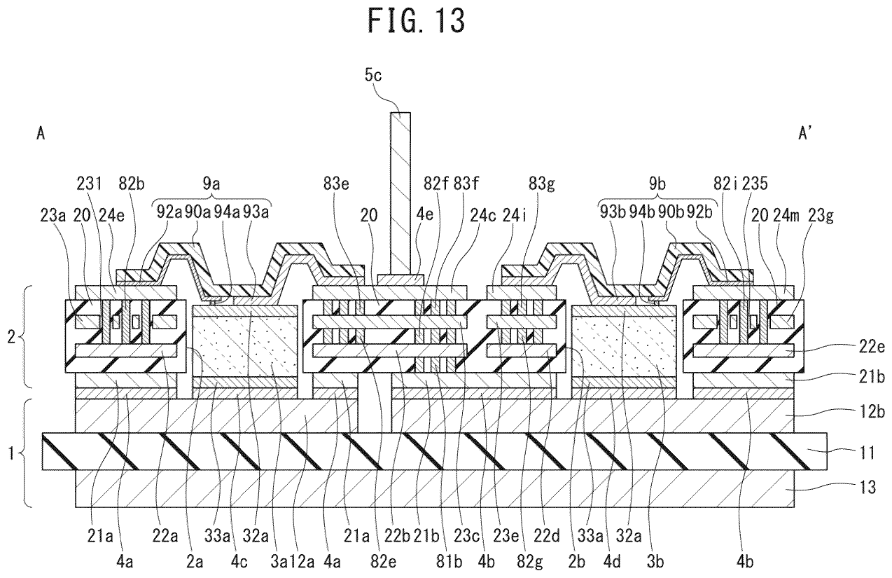

FIG. 12 is a top view illustrating a semiconductor device according to a third embodiment, and FIG. 13 is a cross-sectional view in the vertical direction taken along line A-A′ in FIG. 12. As illustrated in FIG. 12 and FIG. 13, the semiconductor device according to the third embodiment differs from the semiconductor device according to the first embodiment illustrated in FIG. 1 and FIG. 2 in that the semiconductor chips 3a to 3d are connected to the fourth wiring layers 24c, 24d, 24e, 24f, 24g, 24i, 24l, 24m, 14n, and 24o via flexible substrates 9a to 9d that are connection members.

The flexible substrate 9a includes an insulating film (an insulating layer) 90a, and copper foils (conductive layers) 91a, 92a, and 93a provided on the bottom surface of the insulating film 90a. FIG. 12 schematically indicates the copper foils 91a, 92a, and 93a hidden under the insulating film 90a by the broken lines, and the same is also applied to the case of the respective flexible substrates 9b to 9d. The copper foil 91a electrically connects the fourth wiring layer 24d to the gate electrode 31a (refer to FIG. 1) of the semiconductor chip 3a. The copper foil 92a electrically connects the fourth wiring layer 24e to the source electrode 32a (refer to FIG. 1) of the semiconductor chip 3a. The copper foil 93a electrically connects the source electrode 32a (refer to FIG. 1) of the semiconductor chip 3a to the fourth wiring layer 24c.

As illustrated in FIG. 13, the copper foil 92a has a smaller thickness than the copper foil 93a. The copper foil 92a is bonded to the source electrode 32a of the semiconductor chip 3a via a copper bump 94a. The copper foil 91a illustrated in FIG. 12 has a smaller thickness than the copper foil 93a. The copper foil 91a is bonded to the gate electrode 31a of the semiconductor chip 3a via a copper bump (not illustrated) similar to the copper bump 94a.

The flexible substrate 9b includes an insulating film 90b, and copper foils 91b, 92b, and 93b provided on the bottom surface of the insulating film 90b. The copper foil 91b electrically connects the fourth wiring layer 24l to the gate electrode 31b (refer to FIG. 1) of the semiconductor chip 3b. The copper foil 92b electrically connects the fourth wiring layer 24m to the source electrode 32b (refer to FIG. 1) of the semiconductor chip 3b. The copper foil 93b electrically connects the source electrode 32b (refer to FIG. 1) of the semiconductor chip 3b to the fourth wiring layer 24i.

As illustrated in FIG. 13, the copper foil 92b has a smaller thickness than the copper foil 93b. The copper foil 92b is bonded to the source electrode 32b of the semiconductor chip 3b via a copper bump 94b. The copper foil 91b illustrated in FIG. 12 has a smaller thickness than the copper foil 93b. The copper foil 91b is bonded to the gate electrode 31b of the semiconductor chip 3b via a copper bump (not illustrated) similar to the copper bump 94b.

The flexible substrate 9c illustrated in FIG. 12 includes an insulating film 90c, and copper foils 91c, 92c, and 93c provided on the bottom surface of the insulating film 90c. The copper foil 91c electrically connects the fourth wiring layer 24f to the gate electrode 31c (refer to FIG. 1) of the semiconductor chip 3c. The copper foil 92c electrically connects the fourth wiring layer 24g to the source electrode 32c (refer to FIG. 1) of the semiconductor chip 3c. The copper foil 93c electrically connects the source electrode 32c (refer to FIG. 1) of the semiconductor chip 3c to the fourth wiring layer 24c. The flexible substrate 9c has the same structure as the respective flexible substrates 9a and 9b.

The flexible substrate 9d illustrated in FIG. 12 includes an insulating film 90d, and copper foils 91d, 92d, and 93d provided on the bottom surface of the insulating film 90d. The copper foil 91d electrically connects the fourth wiring layer 24n to the gate electrode 31d (refer to FIG. 1) of the semiconductor chip 3d. The copper foil 92d electrically connects the fourth wiring layer 24o to the source electrode 32d (refer to FIG. 1) of the semiconductor chip 3d. The copper foil 93d electrically connects the source electrode 32d (refer to FIG. 1) of the semiconductor chip 3d to the fourth wiring layer 24i. The flexible substrate 9d has the same structure as the respective flexible substrates 9a and 9b. The other configurations of the semiconductor device according to the third embodiment are substantially the same as those of the semiconductor device according to the first embodiment, and overlapping explanations are not repeated below.

The configuration of the semiconductor device according to the third embodiment enables a reduction in size (high-density packaging) of the semiconductor module, and can also facilitate the alignment during the packaging of the components and the inspection of the bonded parts, so as to avoid a decrease in quality of products, as in the case of the semiconductor device according to the first embodiment. Further, the use of the flexible substrates 9a to 9d that are the connection members can improve the reliability of the device.

### Fourth Embodiment

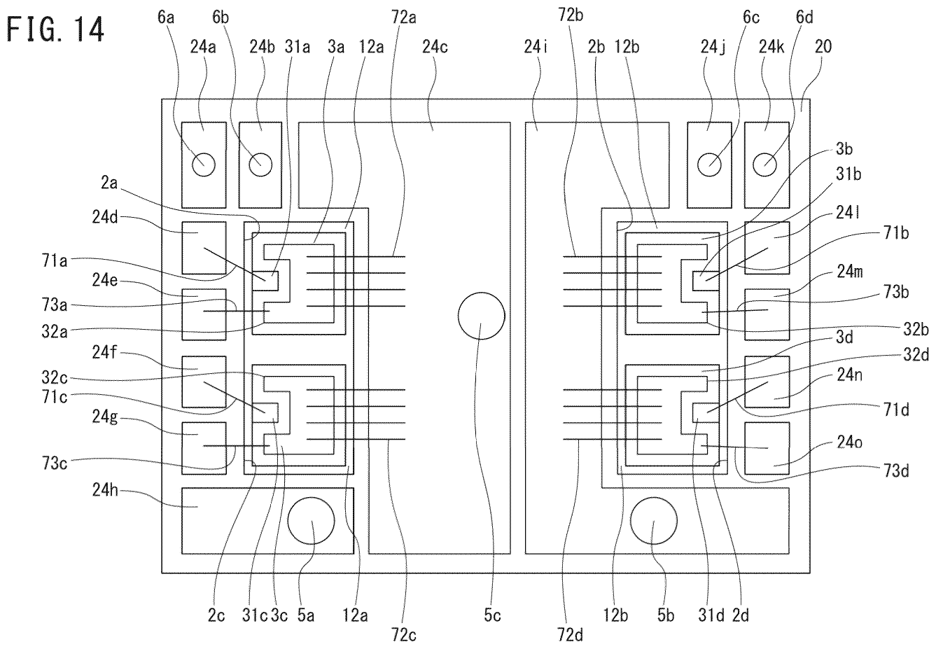

FIG. 14 is a top view illustrating a semiconductor device according to a fourth embodiment. As illustrated in FIG. 14, the semiconductor device according to the fourth embodiment differs from the semiconductor device according to the first embodiment illustrated in FIG. 1 in that the insulating layer 20 of the printed circuit board 2 is not interposed between the respective semiconductor devices 3a and 3c or between the respective semiconductor devices 3b and 3d. The opening 2a surrounding the semiconductor chip 3a and the opening 2c surrounding the semiconductor chip 3c each provided in the insulating layer 20 of the printed circuit board 2 are integrated with each other. Similarly, the opening 2b surrounding the semiconductor chip 3b and the opening 2d surrounding the semiconductor chip 3d each provided in the insulating layer 20 of the printed circuit board 2 are integrated with each other. The other configurations of the semiconductor device according to the fourth embodiment are substantially the same as those of the semiconductor device according to the first embodiment, and overlapping explanations are not repeated below.

The configuration of the semiconductor device according to the fourth embodiment enables a reduction in size (high-density packaging) of the semiconductor module, and can also facilitate the alignment during the packaging of the components and the inspection of the bonded parts, so as to avoid a decrease in quality of products, as in the case of the semiconductor device according to the first embodiment.

### Fifth Embodiment

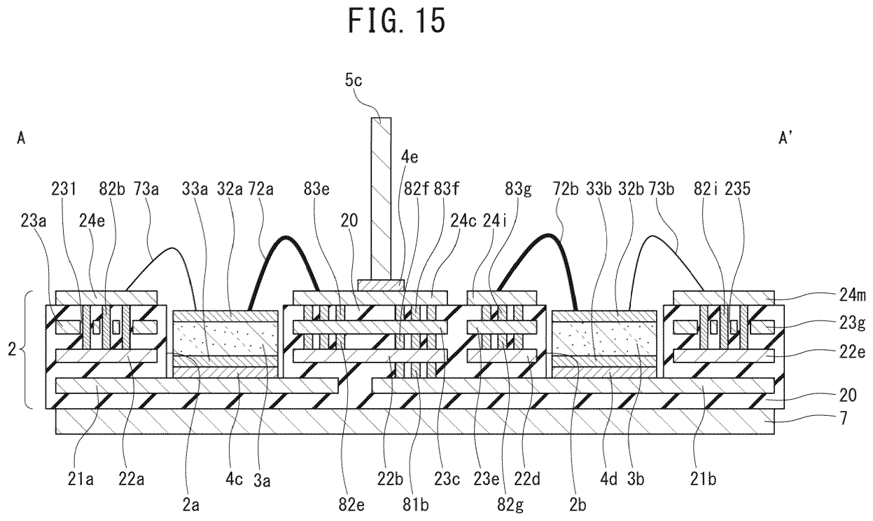

FIG. 15 is a cross-sectional view illustrating a semiconductor device according to a fifth embodiment. As illustrated in FIG. 15, the semiconductor device according to the fifth embodiment differs from the semiconductor device according to the first embodiment illustrated in FIG. 2 in that the insulated circuit substrate 1 is not provided but the semiconductor chips 3a and 3b are arranged in a part of the printed circuit board 2.

The respective first wiring layers 21a and 21b of the printed circuit board 2 are buried inside the insulating layer 20. A metal plate 7 is deposited on the bottom surface side of the respective first wiring layers 21a and 21b with the insulating layer 20 interposed. The metal plate 7 includes metal such as copper, for example.

The respective top surfaces of the first wiring layers 21a and 21b are partly exposed to the respective openings 2a and 2b of the insulating layer 20. The semiconductor chip 3a is bonded to the exposed top surface of the first wiring layer 21a. The semiconductor chip 3a is provided inside the opening 2a. The semiconductor chip 3b is bonded to the exposed top surface of the first wiring layer 21b. The semiconductor chip 3b is provided inside the opening 2b. The other configurations of the semiconductor device according to the fifth embodiment are substantially the same as those of the semiconductor device according to the first embodiment, and overlapping explanations are not repeated below.

The configuration of the semiconductor device according to the fifth embodiment enables a reduction in size (high-density packaging) of the semiconductor module, and can also facilitate the alignment during the packaging of the components and the inspection of the bonded parts, so as to avoid a decrease in quality of products, as in the case of the semiconductor device according to the first embodiment.

### Other Embodiments

As described above, the present invention has been described according to the first to fifth embodiments, but it should not be understood that the description and drawings implementing a portion of this disclosure limit the present invention. Various alternative embodiments of the present invention, examples, and operational techniques will be apparent to those skilled in the art from this disclosure.

For example, while the respective semiconductor devices according to the first to fifth embodiments are illustrated above with the “2-in-1” semiconductor module having the functions for two power semiconductor elements, the present invention is not limited to this case, and may also be applied to a “1-in-1” semiconductor module having functions for one power semiconductor element.

Further, while the respective semiconductor devices according to the first to fifth embodiments are illustrated above with the case in which the printed circuit board 2 includes the four wiring layers, the present invention is not limited to this case, and the number of the layers to be provided can be changed as appropriate depending on the complexity of the circuit pattern, the flowing amount of the main current, or the like. For example, the printed circuit board 2 may include five or more wiring layers. Alternatively, the printed circuit board 2 may include three wiring layers such that the third wiring layers 23a and 23g electrically connected to the gate control terminals 6a and 6d are arranged at the same level as the second wiring layers 22a and 22e electrically connected to the auxiliary source terminals 6b and 6c, or the auxiliary source terminals 6b and 6c are both not provided.

Further, the respective semiconductor devices according to the first to fifth embodiments are illustrated above with the case of including the third wiring layers 23a and 23g electrically connected to the gate control terminals 6a and 6d each as an upper layer and including the second wiring layers 22a and 22e electrically connected to the auxiliary source terminal 6b each as a lower layer, but the positional relation between the upper layers and the lower layers may be reversed.

The configurations disclosed in the first to fifth embodiments may be combined as appropriate within a range that does not contradict with the scope of the respective embodiments. As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present specification.

What is claimed is:

1. A semiconductor device comprising:
first and second semiconductor chips provided separately from each other, each semiconductor chip including a first main electrode on a top surface side and a second main electrode on a bottom surface side; and
a printed circuit board provided at a circumference of the first and second semiconductor chips, the printed circuit board including
a plurality of wiring layers including a first wiring layer which is an uppermost layer electrically connected to the first main electrode of the first semiconductor chip through a connection member, and a second wiring layer which is a lowermost layer electrically connected to the first wiring layer through a via and further to the second main electrode of the second semiconductor chip, and
an insulating layer provided between the respective wiring layers.

2. The semiconductor device of claim 1, wherein the connection member is any of a bonding wire, a lead frame, or a flexible substrate.

3. The semiconductor device of claim 1, further comprising an external connection terminal electrically connected to the first wiring layer.

4. The semiconductor device of claim 1, wherein the plural wiring layers further include a third wiring layer which is the uppermost layer provided separately from the first wiring layer and electrically connected to the first main electrode of the second semiconductor chip through a connection member.

5. The semiconductor device of claim 4, further comprising an external connection terminal electrically connected to the third wiring layer.

6. The semiconductor device of claim 1, wherein the plural wiring layers further include:
a third wiring layer which is the lowermost layer provided separately from the second wiring layer and electrically connected to the second main electrode of the first semiconductor chip; and
a fourth wiring layer which is the uppermost layer provided separately from the first wiring layer and electrically connected to the third wiring layer through a via.

7. The semiconductor device of claim 6, further comprising an external connection terminal electrically connected to the fourth wiring layer.

8. The semiconductor device of claim 1, wherein:
the first semiconductor chip further includes a control electrode on the top surface side; and
the plural wiring layers further include
a third wiring layer which is the uppermost layer provided separately from the first wiring layer and electrically connected to the control electrode of the first semiconductor chip through a connection member,
a fourth wiring layer provided as a lower layer than the third wiring layer and electrically connected to the third wiring layer through a via, and
a fifth wiring layer which is the uppermost layer provided separately from each of the first wiring layer and the third wiring layer and electrically connected to the fourth wiring layer through a via.

9. The semiconductor device of claim 8, further comprising a first control terminal electrically connected to the fifth wiring layer.

10. The semiconductor device of claim 8, wherein the plural wiring layers further include:
a sixth wiring layer which is the uppermost layer provided separately from each of the first wiring layer, the third wiring layer, and the fifth wiring layer and electrically connected to the first main electrode of the first semiconductor chip through a connection member;
a seventh wiring layer provided as a lower layer than the fourth wiring layer and electrically connected to the sixth wiring layer through a via; and
an eighth wiring layer which is the uppermost layer provided separately from each of the first wiring layer, the third wiring layer, the fifth wiring layer, and the sixth wiring layer and electrically connected to the seventh wiring layer through a via.

11. The semiconductor device of claim 10, further comprising a second control terminal electrically connected to the eighth wiring layer.

12. The semiconductor device of claim 10, wherein the fourth wiring layer and the seventh wiring layer are opposed to each other with the insulating layer interposed.

13. The semiconductor device of claim 12, wherein the via connecting the seventh wiring layer and the eighth wiring layer penetrates a through-hole provided in the fourth wiring layer.

14. The semiconductor device of claim 1, wherein the printed circuit board is provided with a first opening surrounding the first semiconductor chip and a second opening surrounding the second semiconductor chip.

15. The semiconductor device of claim 1, further comprising an insulated circuit substrate including:
an insulating substrate;
a first circuit plate and a second circuit plate provided separately from each other on a top surface side of the insulating substrate; and
a heat-releasing plate provided on a bottom surface side of the insulating substrate,
wherein the first semiconductor chip is provided on the first circuit plate, and the second semiconductor chip is provided on the second circuit plate.

16. The semiconductor device of claim 1, wherein:
the plural wiring layers further include a third wiring layer which is the lowermost layer provided separately from the second wiring layer and electrically connected to the second main electrode of the first semiconductor chip;
the second wiring layer and the third wiring layer each have a top surface partly exposed on the insulating layer;
the first semiconductor chip is provided on the exposed top surface of the third wiring layer; and
the second semiconductor chip is provided on the exposed top surface of the second wiring layer.
